(19) United States
(12) Patent Application Publication
(10) Pub. No.: US 2012/0161245 A1
(43) Pub. Date: Jun. 28, 2012

(54) SEMICONDUCTOR DEVICE AND METHOD FOR FABRICATING THE SAME

(75) Inventor: YUICHI HIGUCHI, Osaka (JP)

(73) Assignee: PANASONIC CORPORATION, Osaka (JP)

(21) Appl. No.: 13/399,004

(22) Filed: Feb. 17, 2012

Related U.S. Application Data
(63) Continuation of application No. PCT/JP2010/004887, filed on Aug. 3, 2010.

(30) Foreign Application Priority Data
Dec. 21, 2009 (JP) 2009-289041

(51) Int. Cl. H01L 27/088; H01L 21/336

(52) U.S. Cl. 257/392; 438/301; 257/E27.06; 257/E21.409

(57) ABSTRACT

A semiconductor device includes first and second FETs having the same conductivity type. The first FET includes a first gate electrode, a first side wall, and first extension regions respectively provided in a first active region on both sides of the first gate electrodes. The second FET includes a second gate electrode, a second side wall, and second extension regions respectively provided in a second active region on both sides of the second gate electrode. An overlap of each of the first extension regions and the first gate electrode in a gate length direction is longer than an overlap of each of the second extension regions and the second gate electrode. The distance between the first gate electrode and the first side wall is shorter than the distance between the second gate electrode and the second side wall.

### CROSS-REFERENCE TO RELATED APPLICATIONS

This is a continuation of PCT International Application PCT/JP2010/004887 filed on Aug. 3, 2010, which claims priority to Japanese Patent Application No. 2009-289041 filed on Dec. 21, 2009. The disclosures of these applications including the specifications, the drawings, and the claims are hereby incorporated by reference in their entirety.

### BACKGROUND

In recent years, in order to realize an increase in integration degree of a semiconductor device, the size of each semiconductor element has been reduced. With the reduction in size of the semiconductor element, it has become difficult that, in a semiconductor device (e.g., an embedded static random access memory (eSRAM)) including a plurality of field-effect transistors (hereinafter may be referred to as a “transistor”) having different threshold voltages, the threshold voltages of the transistors are simultaneously optimized.

Various methods for, in a semiconductor device including a plurality of transistors having different threshold voltages on the same substrate, adjusting each of the threshold voltages have been proposed. One of such methods will be described below.

FIGS. 5(a)-5(c) are views illustrating steps for forming a low threshold voltage (Lvt) transistor and a high threshold voltage (Hvt) transistor having different threshold voltages. As illustrated in FIGS. 5(a)-5(c), a surface portion of a semiconductor substrate 101 is divided by shallow trench isolations (STIs) 102 which are element isolations, thereby providing an Lvt transistor formation region RL and an Hvt transistor formation region RH.

First, as illustrated in FIG. 5(a), a resist 103 covering the Hvt transistor formation region RH is formed, and channel implantation is performed to the Lvt transistor formation region RL by using the resist 103 as a mask. This forms a channel layer 104L in an active region of the Lvt transistor formation region RL. Subsequently, the resist 103 is removed.

Next, as illustrated in FIG. 5(b), a resist 105 covering the Lvt transistor formation region RL is formed, and the channel implantation is performed to the Hvt transistor formation region RH by using the resist 105 as a mask. This forms a channel layer 104H in an active region of the Hvt transistor formation region RH. Subsequently, the resist 105 is removed.

After the step illustrated in FIG. 5(b), a gate structure 109 including a gate insulating film 106, a gate electrode 107, and a side wall spacer 108 is formed as illustrated in FIG. 5(c). Further, impurity implantation is performed by using the gate structure 109 as a mask, thereby forming an extension region 110 on each side of the gate structure 109 and a halo region 111 covering a lower side of the extension region 110. Although not shown in the figure, source/drain regions etc. are subsequently formed.

As described above, the channel implantation is performed separately to the Lvt transistor formation region RL and the Hvt transistor formation region RH, and therefore the concentration and type of an impurity can be set separately for the channel layers 104L and 104H. As a result, the threshold voltage can be set separately for both of an Lvt transistor and an Hvt transistor.

Note that, as a reference relating the background art, there is, e.g., Japanese Patent Publication No. 2007-281027.

### SUMMARY

However, the setting only for the impurity of the channel layer limits improvement of performance of each of the Lvt transistor and the Hvt transistor. Facing such limitation, not only the channel implantation but also extension implantation may be performed separately to each type of the transistor. However, it is required that a masking step and an implanting step are separately performed, resulting in a longer fabricating process.

In view of the foregoing, a technique will be described below, by which, in a semiconductor device including a plurality of transistors having different threshold voltages and a method for fabricating the semiconductor device, an increase in number of masking steps is reduced while improving performance of each of the transistors.

A semiconductor device of the present disclosure includes first and second field-effect transistors provided on a substrate and having the same conductivity type. The first field-effect transistor include a first gate electrode formed on a first active region of the substrate, a first side wall spacer formed on a side wall of the first gate electrode, and first extension regions respectively formed in the first active region on sides sandwiching part of the first active region below the first gate electrode and having a first conductivity type. The second field-effect transistor include a second gate electrode formed on a second active region of the substrate, a second side wall spacer formed on a side wall of the second gate electrode, and second extension regions respectively formed in the second active region on sides sandwiching part of the second active region below the second gate electrode and having the first conductivity type. The second field-effect transistor has a threshold voltage higher than that of the first field-effect transistor. The length in a gate length direction, by which each of the first extension regions and the first gate electrode overlap each other, is longer than the length in the gate length direction, by which each of the second extension regions and the second gate electrode overlap each other. The distance between the first gate electrode and the first side wall spacer is shorter than the distance between the second gate electrode and the second side wall spacer.

According to the foregoing semiconductor device, an effective gate length (the distance between the extension regions respectively provided on both sides of the gate electrode) is different between the first and second field-effect transistors depending on a difference in length of an overlap of the extension region and the gate electrode in the gate length direction. Thus, the threshold voltage of the first field-effect transistor is lower than that of the second field-effect transistor. As will be described below, the first and second extension regions can be formed by impurity implantation using a common mask, thereby avoiding an increase in number of masking steps.

It is preferred that a first offset spacer is provided between the first side wall spacer and the first gate electrode, and a second offset spacer thicker than the first offset spacer is provided between the second side wall spacer and the second gate electrode.

The foregoing preferable configuration may be applied in order to provide a difference in distance between the gate electrode and the side wall spacer (the distance between the gate electrode and the side wall spacer in the first field-effect transistor is shorter than that in the second field-effect transistor).

It is preferred that at least the second offset spacer of the first and second offset spacers has a multi-layer structure with two or more layers, and the number of layers of the second offset spacer is greater than that of the first offset spacer.

The foregoing preferable configuration may be applied in order to provide the second offset spacer thicker than the first offset spacer. In such a case, the first offset spacer may have a single-layer structure.

It is preferred that the first side wall spacer contacts the side wall of the first gate electrode, and an offset spacer is provided between the second side wall spacer and the second gate electrode.

The foregoing preferable configuration may be applied in order to provide the difference in distance between the gate electrode and the side wall spacer.

It is preferred that the length in the gate length direction, by which each of the first extension regions and the first gate electrode overlap each other, is longer than the length in the gate length direction, by which each of the second extension regions and the second gate electrode overlap each other, by a predetermined distance.

It is preferred that the distance between the first gate electrode and the first side wall spacer is shorter than the distance between the second gate electrode and the second side wall spacer by a predetermined distance.

It is preferred that the predetermined distance is set depending on a difference between the threshold voltage of the first field-effect transistor and the threshold voltage of the second field-effect transistor.

A difference in predetermined distance results in an effective gate length difference between the field-effect transistors. Thus, a difference in threshold voltage is provided depending on the effective gate length difference. Consequently, the predetermined distance is set depending on a desired difference in threshold voltage.

As one of specific examples, the predetermined distance may be equal to or greater than 2 nm and equal to or less than 4 nm.

It is preferred that the dimension of the first gate electrode in the gate length direction and the dimension of the second gate electrode in the gate length direction are substantially the same.

The phrase “substantially the same” means that design dimensions are the same within a reasonable fabricating tolerances of the device.

It is preferred that the distance of part of the first extension region below the first gate electrode is shorter than the distance of part of the second extension region below the second gate electrode.

Even if the dimensions of the gate electrodes themselves are the same, the effective gate length difference between the field-effect transistors can be provided by the difference in configuration of the extension region as described above.

It is preferred that the semiconductor device further includes a first halo region provided between each of the first extension regions and the substrate and having a second conductivity type; and a second halo region provided between each of the second extension regions and the substrate and having the second conductivity type.

It is preferred that the semiconductor device further includes first source/drain regions each formed in the first active region on an outer side relative to each of the first extension regions as viewed from the first gate electrode and having the first conductivity type; and second source/drain regions each formed in the second active region on an outer side relative to each of the second extension regions as viewed from the second gate electrode.

The semiconductor device may include the foregoing components.

According to the present disclosure, in a first method for fabricating a semiconductor device including a first field-effect transistor having a first gate electrode and a second field-effect transistor having a second gate electrode, the first method includes forming the first gate electrode on a first active region of a substrate and forming the second gate electrode on a second active region of the substrate; forming a first offset spacer on a side wall of the first gate electrode and forming a second offset spacer thicker than the first offset spacer on a side wall of the second gate electrode; and, after the forming the first and second offset spacers, performing first impurity implantation to the first active region by using the first gate electrode and the first offset spacer as a mask to respectively form first extension regions having a first conductivity type in the first active region on both sides relative to the first gate electrode, and performing the first impurity implantation to the second active region by using the second gate electrode and the second offset spacer as a mask to respectively form second extension regions having the first conductivity type in the second active region on both sides relative to the second gate electrode.

In the first method, since the impurity implantation is performed at the same step, i.e., in the performing first impurity implantation, the distance of part of the extension region extending from an end of the offset spacer toward the gate electrode is the same between the first and second field-effect transistors. However, since the second offset spacer is thicker than the first offset spacer, the length in the gate length direction, by which each of the first extension regions and the first gate electrode overlap each other, is longer than the length in the gate length direction, by which each of the second extension regions and the second gate electrode overlap each other. As a result, the threshold voltage of the second field-effect transistor is higher than that of the first field-effect transistor.

By using the same impurity implantation as described above, the plurality of field-effect transistors having different threshold voltages can be formed without increasing the number of masking steps.

It is preferred that at least the second offset spacer of the first and second offset spacers has a multi-layer structure with two or more layers, and the number of layers of the second offset spacer is greater than that of the first offset spacer.

The foregoing preferable configuration may be applied in order to provide the second offset spacer thicker than the first offset spacer.

According to the present disclosure, in a second method for fabricating a semiconductor device including a first field-effect transistor having a first gate electrode and a second field-effect transistor having a second gate electrode, the second method includes forming the first gate electrode on a first active region of a substrate and forming the second gate electrode on a second active region of the substrate; forming an offset spacer on a side wall of the second gate electrode; and, after the forming an offset spacer, performing first impurity implantation to the first active region by using the first gate electrode as a mask to respectively form first extension regions having a first conductivity type in the first active region on both sides relative to the first gate electrode, and performing the first impurity implantation to the second active region by using the second gate electrode and the offset spacer as a mask to respectively form second extension regions having the first conductivity type in the second active region on both sides relative to the second gate electrode. In the performing first impurity implantation, the first impurity implantation is performed in a state in which an offset spacer is not formed on a side wall of the first gate electrode.

In the second method, the impurity implantation is also performed at the same step, i.e., in the performing first impurity implantation. In the second method, the offset spacer is provided on the side wall of the second gate electrode, and the offset spacer is not provided on the side wall of the first gate electrode. Thus, the length in the gate length direction, by which the first extension region and the first gate electrode overlap each other, is longer than the length in the gate length direction, by which the second extension region and the second gate electrode overlap each other. By using the same impurity implantation as described above, the plurality of field-effect transistors having different threshold voltages can be formed without increasing the number of masking steps.

In each of the first and second methods, after the performing first impurity implantation, first and second side wall spacers may be formed on the side walls of the first and second gate electrodes, respectively. Second impurity implantation may be then performed to the first and second active regions to form first source/drain regions having the first conductivity type in the first active region on an outer side relative to the first side wall spacer as viewed from the first gate electrode and form second source/drain regions having the first conductivity type in the second active region on an outer side relative to the second side wall spacer as viewed from the second gate electrode.

In the foregoing manner, the source/drain regions can be formed in each of the first and second field-effect transistors.

According to the semiconductor device and the method for fabricating the semiconductor device in the present disclosure, the effective gate length difference between the plurality of field-effect transistors can be provided by using the same impurity implantation. Thus, the plurality of field-effect transistors having different threshold voltages can be formed while avoiding the increase in number of masking steps.

### BRIEF DESCRIPTION OF THE DRAWINGS

FIGS. 1(a)-1(c) are views schematically illustrating an example semiconductor device and a method for fabricating the example semiconductor device in a first embodiment of the present disclosure.

FIGS. 2(a)-2(c) are views schematically illustrating, subsequent to FIG. 1(c), the example semiconductor device and the method for fabricating the example semiconductor device in the first embodiment of the present disclosure.

FIGS. 3(a)-3(c) are views schematically illustrating an example semiconductor device and a method for fabricating the example semiconductor device in a second embodiment of the present disclosure.

FIGS. 4(a)-4(c) are views schematically illustrating, subsequent to FIG. 3(c), the example semiconductor device and the method for fabricating the example semiconductor device in the second embodiment of the present disclosure.

FIGS. 5(a)-5(c) are views illustrating a method for fabricating a semiconductor device of the background art.

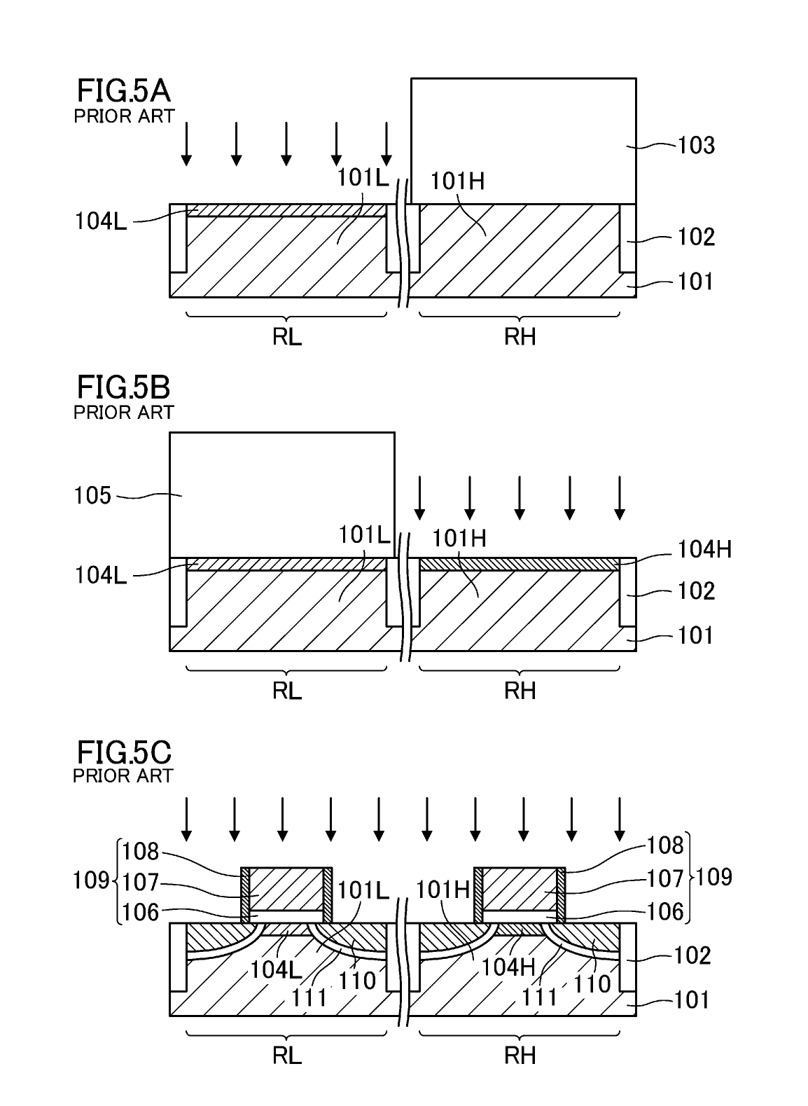

### DETAILED DESCRIPTION

### First Embodiment

A semiconductor device and a method for fabricating the semiconductor device in a first embodiment of the present disclosure will be described below with reference to the drawings.

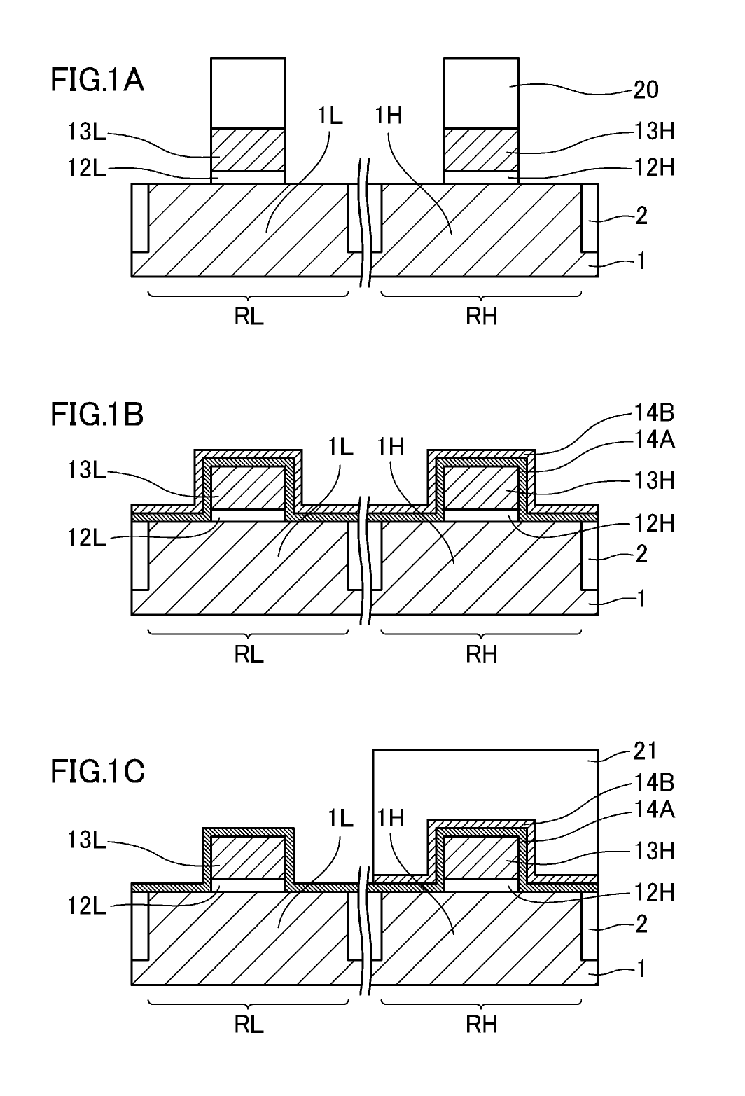

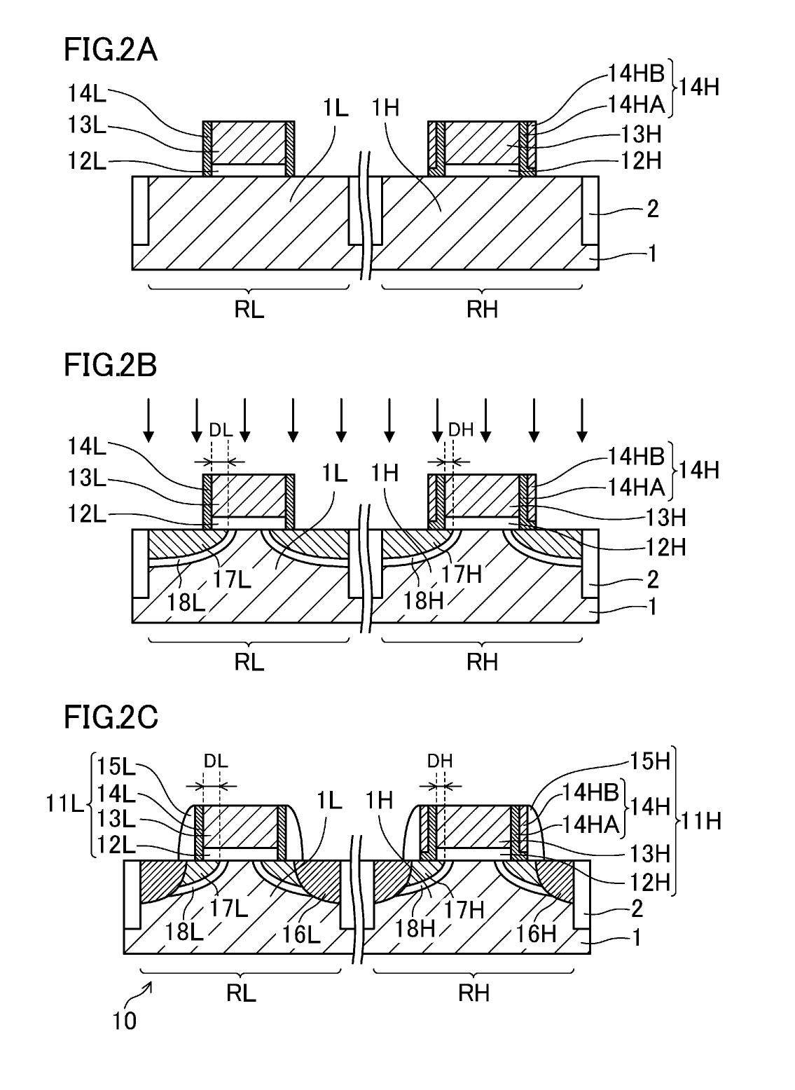

FIGS. 1(a)-1(c) and 2(a)-2(c) are views schematically illustrating a structure of an example semiconductor device 10 of the present embodiment and a method for fabricating the semiconductor device 10. As illustrated in FIG. 2(c), the semiconductor device 10 is formed by using a substrate 1 which is, e.g., a semiconductor substrate made of silicon. Element isolation regions 2 formed by, e.g., local oxidation of silicon (LOCOS) or shallow trench isolation (STI) and made of a silicon oxide film divide a surface portion of the substrate 1 into active regions which are part of the substrate 1. FIG. 2(c) illustrates an Lvt transistor formation region RL where a field-effect transistor (hereinafter referred to as an “Lvt transistor”) having a low threshold voltage is formed and an Hvt transistor formation region RH where a field-effect transistor (hereinafter referred to as an “Hvt transistor”) having a higher threshold voltage than that of the Lvt transistor is formed. Note that, in the present embodiment, N-type FETs will be described as the Lvt and Hvt transistors.

In the Lvt transistor formation region RL, a gate electrode 13L is formed on an active region 1L of the P-type substrate 1 surrounded by the element isolation regions 2 with a gate insulating film 12L being interposed between the gate electrode 13L and the active region 1L. A side wall spacer 15L is formed on a side wall of the gate electrode 13L with an offset spacer 14L being interposed between the side wall spacer 15L and the gate electrode 13L. An N-type source/drain region 16L (a source region and a drain region are collectively referred to as a “source/drain region”) is formed in the active region 1L on each side of the gate electrode 13L (on an outer side relative to the side wall spacer 15L). Further, in part of the active region 1L on an inner side (on a side closer to the gate electrode 13L) relative to the N-type source/drain regions 16L, an N-type extension region 17L is formed on each side of a channel formation region of the active region 1L below the gate electrode 13L. Part of each of the N-type extension regions 17L extends from the side of the gate electrode 13L to below the gate electrode 13L. A P-type halo region 18L having a conductivity type different from that of the N-type extension region 17L is formed between each of the N-type extension regions 17L and the substrate 1. The halo region 18L is formed so as to cover bottom and side surfaces (except for a side surface connected to the source/drain region 16L) of the N-type extension region 17L.

The gate insulating film 12L, the gate electrode 13L, the offset spacer 14L, and the side wall spacer 15L form a gate structure 11L of the Lvt transistor.

Next, in the Hvt transistor formation region RH, the Hvt transistor having a similar structure to that of the Lvt transistor of the Lvt transistor formation region RL is formed. Specifically, a gate electrode 13H is formed on an active region 1H of the P-type substrate 1 surrounded by the element isolation regions 2 with a gate insulating film 12H being interposed between the gate electrode 13H and the active region 1H. A side wall spacer 15H is formed on a side wall of the gate electrode 13H with an offset spacer 14H being interposed between the side wall spacer 15H and the gate electrode 13H. An N-type source/drain region 16H is formed in the active region 1L on each side of the gate electrode 13H. N-type extension regions 17H, part of each of which extends to below the gate electrode 13H, are formed on an inner side relative to the source/drain regions 16H. A P-type halo region 18H having a conductivity type different from that of the extension region 17H is formed between each of the extension regions 17H and the substrate 1. The halo region 18H is formed so as to cover bottom and side surfaces (except for a side surface connected to the source/drain region 16H) of the extension region 17H.

The gate insulating film 12H, the gate electrode 13H, the offset spacer 14H, and the side wall spacer 15H form a gate structure 11H of the Hvt transistor.

The offset spacer 14H of the Hvt transistor has a double-layer structure of a first layer 14HA having an L-shaped cross section contacting the side wall of the gate electrode 13H and a second layer 14HB stacked on the first layer 14HA. The total thickness of the two layers is greater than the thickness of the offset spacer 14L having a single-layer structure in the Lvt transistor.

Suppose that the length of part of the extension region 17L extending to below the gate electrode 13L in the Lvt transistor (an overlap amount of the extension region 17L and the gate electrode 13L) is represented by a reference character “DL,” and the length of part of the extension region 17H extending to below the gate electrode 13H in the Hvt transistor is represented by a reference character “DH.” The length DL is longer than the length DH. In other words, the length DL by which the gate electrode 13L and the extension region 17L overlap each other is longer than the length DH by which the gate electrode 13H and the extension region 17H overlap each other. That is, the extension region 17L of the Lvt transistor further extends toward an inside of the gate electrode as compared to the extension region 17H of the Hvt transistor.

The dimension of the gate electrode 13L in a gate length direction and the dimension of the gate electrode 13H in the gate length direction are substantially the same. The phrase “substantially the same” means that design dimensions are the same within a reasonable fabricating tolerances of the device.

Thus, the distance (effective gate length) of part of the extension region 17L below the gate electrode 13L in the Lvt transistor is shorter than the distance of part of the extension region 17H below the gate electrode 13H in the Hvt transistor.

This allows the threshold voltage of the Lvt transistor to be lower than that of the Hvt transistor.

A difference between the overlap amount DL and the overlap amount DH is determined depending on a difference between the thickness of the offset spacer 14L and the thickness of the offset spacer 14H.

The Lvt transistor formed in the Lvt transistor formation region RL is a transistor for which, e.g., an increase in operation speed is more emphasized as compared to reduction in off-leakage current (i.e., a transistor for which gate induced drain leakage (GIDL) current, band-to-band tunneling (BTBT) current, etc. can be ignored). The offset spacer 14L is set so as to be thinner in order to ensure the sufficiently long overlap amount DL, thereby reducing the threshold voltage of the Lvt transistor.

On the other hand, the Hvt transistor formed in the Hvt transistor formation region RH is a transistor for which the reduction in off-leakage current is more emphasized as compared to the Lvt transistor (i.e., a transistor for which the GIDL current, the BTBT current, etc. cannot be ignored). In order to ensure the shorter overlap amount DH (as compared to the overlap amount DL), the offset spacer 14H is set so as to be thicker than the offset spacer 14L. Note that each of the extension regions 17H is not offset from the gate electrode 13H (a state in which each of the extension regions 17H is not arranged below the gate electrode 13H is not caused).

As described above, the thicknesses of the overlap spacers are separately set, thereby determining the overlap amount of the extension region and the gate electrode. Consequently, the threshold voltage of each of the transistors can be set.

Next, the method for fabricating the semiconductor device 10 will be described with reference to FIGS. 1(a)-1(c) and 2(a)-2(c).

FIG. 1(a) illustrates a state in which gate electrodes are formed. First, e.g., boron (B) ion which is a P-type impurity is implanted to a semiconductor substrate made of P-type single-crystal silicon, i.e., a P-type substrate 1 which is, e.g., a semiconductor substrate provided with P-type well regions and made of single-crystal silicon. This process is performed under predetermined conditions for implanting an impurity to a channel formation region formed in a surface of the substrate 1. Subsequently, a P-type channel diffusion layer (not shown in the figure) is formed by thermal treatment.

Next, an Lvt transistor formation region RL where a field-effect transistor having a lower threshold voltage is formed and an Hvt transistor formation region RH where a field-effect transistor having a higher threshold voltage is formed are defined, and the channel formation region of the substrate 1 is partially exposed. Element isolation regions 2 are formed in a surface portion of the substrate 1 by, e.g., LOCOS or STI. This forms active regions 1L and 1H, each of which is part of the substrate 1 surrounded by the element isolation regions 2.

Next, an insulating film to be formed into gate insulating films 12L and 12H is formed so as to cover the substrate 1, and an electrode material layer to be formed into gate electrodes 13L and 13H is further formed on the insulating film.

The insulating film may be a single-layer film of SiO₂, SiON, HfSiO, HfSiON, HfO₂, etc., or may be a multi-layer film thereof. For example, the following may be used for the formation of the insulating film: thermal oxidation; physical vapor deposition (hereinafter referred to as “PVD”); and chemical vapor deposition (hereinafter referred to as “CVD”).

In addition, the electrode material layer may be a single-layer structure of metal materials such as Ta, TaN, Ti, TiN, Al, and TiAl, or may be a multi-layer structure thereof. Further, the electrode material layer may be a multi-layer structure including the following: a metal layer made of any one of the foregoing metal materials; and a Si layer formed on the metal layer or a Si-containing layer made of a material containing Si and formed on the metal layer. The foregoing layers may be formed by, e.g., the PVD, the CVD, or sputtering.

Next, after a resist material is applied to the electrode material layer, patterning is performed corresponding to a formation position of the gate electrode 13L of the Lvt transistor formation region RL and a formation position of the gate electrode 13H of the Hvt transistor formation region RH, thereby forming a resist 20. Subsequently, the electrode material layer and the insulating film are etched by using the resist 20 as a mask. In such a manner, the gate insulating film 12L and the gate electrode 13L are formed on the active region 1L in the Lvt transistor formation region RL, and the gate insulating film 12H and the gate electrode 13H are formed on the active region 1H in the Hvt transistor formation region RH. Then, the resist 20 is removed.

Next, a step illustrated in FIG. 1(b) is performed. First, an insulating film to be formed into offset spacers is formed on the entire surface of the substrate 1 so as to cover upper and side surfaces of the gate electrodes 13L and 13H. A specific example is as follows. After an insulating film 14A which is a SiN film having a film thickness of 2-10 nm is deposited, an insulating film 14B which is a SiO₂ film having a film thickness of 2-10 nm is deposited so as to cover the insulating film 14A. For example, the CVD may be used as a formation method. In the present embodiment, the insulating film 14A is the SiN film, and the insulating film 14B is the SiO₂ film. However, materials of such films may be switched. In addition, as long as the insulating film 14B can be selectively removed corresponding to the insulating film 14A, other material may be used for each film.

Next, a step illustrated in FIG. 1(c) is performed. First, after a resist material is applied to the entire surface of the substrate 1, patterning is performed so that only the Hvt transistor formation region RH is masked, thereby forming a resist 21. Subsequently, wet etching is performed by using the resist 21 as a mask, and only the insulating film 14B on the Lvt transistor formation region RL is selectively removed. Then, the resist 21 is removed. This results in a state in which only the insulating film 14A remains after the insulating film 14B on the active region 1L is removed, and both of the insulating films 14A and 14B remain on the active region 1H.

Next, as illustrated in FIG. 2(a), anisotropic etching is performed to etch back the entirety of the insulating films 14A and 14B. Then, other than part of the insulating films 14A and 14B covering side walls of the gate electrodes, the insulating films 14A and 14B are removed. In such a manner, offset spacers are formed. More specifically, on the side wall of the gate electrode 13L in the Lvt transistor formation region RL, an offset spacer 14L having a single-layer structure is formed from the insulating film 14A. In addition, on the side wall of the gate electrode 13H in the Hvt transistor formation region RH, an offset spacer 14H having a double-layer structure of a first layer 14HA formed from the insulating film 14A and having an L-shaped cross section and a second layer 14HB formed on the first layer 14HA is formed.

The offset spacer 14H in the Hvt transistor formation region RH has the structure in which the second layer 14HB is stacked on the first layer 14HA formed from the same insulating film 14A as that of the offset spacer 14L in the Lvt transistor formation region RL. Thus, the offset spacer 14H is thicker than the offset spacer 14L by a film thickness of the second layer 14HB.

Next, as illustrated in FIG. 2(b), extension regions and halo regions are formed.

First, ion implantation of As or P which is an N-type impurity is performed as extension implantation. Implantation conditions, e.g., when the ion implantation of As is performed are as follows: implantation energy of 2 keV; a dose amount of 1-2×10¹⁵/cm²; and an implantation angle of 0° (an angle formed between a principal surface of the substrate 1 and a normal line thereof).

In such a state, in the Lvt transistor formation region RL, the gate electrode 13L and the offset spacer 14L are used as a mask to form N-type extension regions 17L in the active region 1L, and, as a result, each of the extension regions 17L is formed below the gate electrode 13L so as to overlap the gate electrode 13L by an overlap amount DL.

On the other hand, in the Hvt transistor formation region RH, the gate electrode 13H and the offset spacer 14H thicker than the offset spacer 14L in the Lvt transistor formation region RL are used as a mask to form N-type extension regions 17H in the active region 1H, and, as a result, each of the extension regions 17H is formed below the gate electrode 13H so as to overlap the gate electrode 13H by an overlap amount DH.

The offset spacer 14L is thinner than the offset spacer 14H. Thus, even if the extension implantation is similarly performed to the Lvt transistor formation region RL and the Hvt transistor formation region RH, the overlap amount DL is longer than the overlap amount DH. Thus, it is not necessary that, for the purpose of providing a difference in effective gate length, the extension implantation is performed separately to the Lvt transistor formation region RL and the Hvt transistor formation region RH. This allows that the plurality of field-effect transistors having different threshold voltages are provided on the same substrate without increasing the number of masking steps.

Subsequently, P-type halo regions 18L and 18H covering lower sides of the extension regions 17L and 17H and each positioned between the substrate 1 and each of the extension regions 17L and 17H are formed. For the formation of the halo regions 18L and 18H, ion implantation of B, BF₂, or In which is a P-type impurity is performed. Implantation conditions, e.g., when the ion implantation of B is performed are as follows: implantation energy of 5-10 keV; a dose amount of 1-4×10¹³/cm²; and an implantation angle of 15-38°.

A difference between the thickness of the offset spacer 14L in the Lvt transistor formation region RL and the thickness of the offset spacer 14H in the Hvt transistor formation region RH will be described.

In the semiconductor device 10, a threshold voltage difference between the Lvt transistor having the lower threshold voltage and the Hvt transistor having the higher threshold voltage is determined depending on an effective gate length difference (difference in distance of part of the extension region below the gate electrode) between the Lvt transistor and the Hvt transistor. Since the effective gate length difference is determined depending on a difference between the overlap amounts DL and DH, the thickness difference between the offset spacers is set depending on a required gate length difference.

Specifically, it is desired that the threshold voltage difference between the Lvt transistor having the lower threshold voltage and the Hvt transistor having the higher threshold voltage is, e.g., about 50-100 mV. If the effective gate length varies by 8 nm, the threshold voltage varies by 100 mV. In such a case, in order to provide an effective gate length difference of 4-8 nm, an offset spacer thickness difference of 2-4 nm (4-8 nm in total) is also provided on each side of the gate electrode. That is, the offset spacer 14H in the Hvt transistor formation region RH is set so as to be thicker than the offset spacer 14L in the Lvt transistor formation region RL by 2-4 nm. In other words, the film thickness of the second layer 14HB of the offset spacer 14H may be set to 2-4 nm.

Thus, the overlap amount DH is increased (as compared to the overlap amount DL) by 2-4 nm on each side of the gate electrode 13H, thereby obtaining an effective gate length difference of 4-8 nm.

Note that the foregoing values have been set forth for purpose of preferred example when the dimension of each of the gate electrodes 13L and 13H themselves in the gate length direction is about 40 nm, and the present disclosure is not limited to such values. The offset spacer thickness difference can be set based on, e.g., the dimension of the gate electrode, the concentrations of various impurity regions (e.g., the extension region and the source/drain region), and the desired threshold voltage difference.

Subsequently, as illustrated in FIG. 2(c), side wall spacers and source/drain regions are formed.

First, an insulating film which is a single-layer film made of SiO₂, SiN or SiON or a multi-layer film made thereof is formed on the substrate 1 so as to cover the gate electrode 13L and 13H etc. Next, anisotropic dry etching is performed for the insulating film, thereby removing the insulating film other than part of the insulating film covering the side walls of the gate electrodes 13L and 13H. In such a manner, a side wall spacer 15L is formed on the side wall of the gate electrode 13L with the offset spacer 14L being interposed between the side wall spacer 15L and the gate electrode 13L, whereas a side wall spacer 15H is formed on the side wall of the gate electrode 13H with the offset spacer 14H being interposed between the side wall spacer 15H and the gate electrode 13H. As a result, the distance between the gate electrode 13L and the side wall spacer 15L is shorter than the distance between the gate electrode 13H and the side wall spacer 15H.

After the foregoing steps, a gate structure 11L is formed in the Lvt transistor formation region RL, and a gate structure 11H is formed in the Hvt transistor formation region RH.

Subsequently, ion implantation of an N-type impurity such as As is performed to the active regions 1L and 1H by using the gate structures 11L and 11H as a mask, thereby forming an N-type source/drain region 16L on each side of the gate structure 11L and forming an N-type source/drain region 16H on each side of the gate structure 11H.

In the foregoing manner, a semiconductor device 10 including the Lvt transistor and the Hvt transistor on the same substrate is formed. According to the foregoing fabricating method, the field-effect transistors having different threshold voltages can be formed without increasing the number of masking steps, thereby shortening a fabricating process.

Note that, although the example where the offset spacer 14H is formed so as to have the double-layer structure and therefore is thicker than the offset spacer 14L having the single-layer structure has been described, other technique may be employed to provide a thickness difference. The offset spacer 14L may be formed so as to have a multi-layer structure including a plurality of layers, and the offset spacer 14H including layers more than the number of layers of the offset spacer 14L may be provided.

In addition, the example where the two types of field-effect transistors are formed has been described above, but the present disclosure is not limited to such a configuration. For example, an Mvt transistor having an intermediate threshold voltage between the threshold voltage of the Lvt transistor and the threshold voltage of the Hvt transistor may be provided in addition to the Lvt transistor and the Hvt transistor. In such a case, an offset spacer having an intermediate thickness between the thickness of the offset spacer 14L and the thickness of the offset spacer 14H may be provided. Alternatively, the present disclosure may be applied in a case where, e.g., SRAM transistors are provided.

### Second Embodiment

Next, a semiconductor device and a method for fabricating the semiconductor device in a second embodiment of the present disclosure will be described with reference to the drawings.

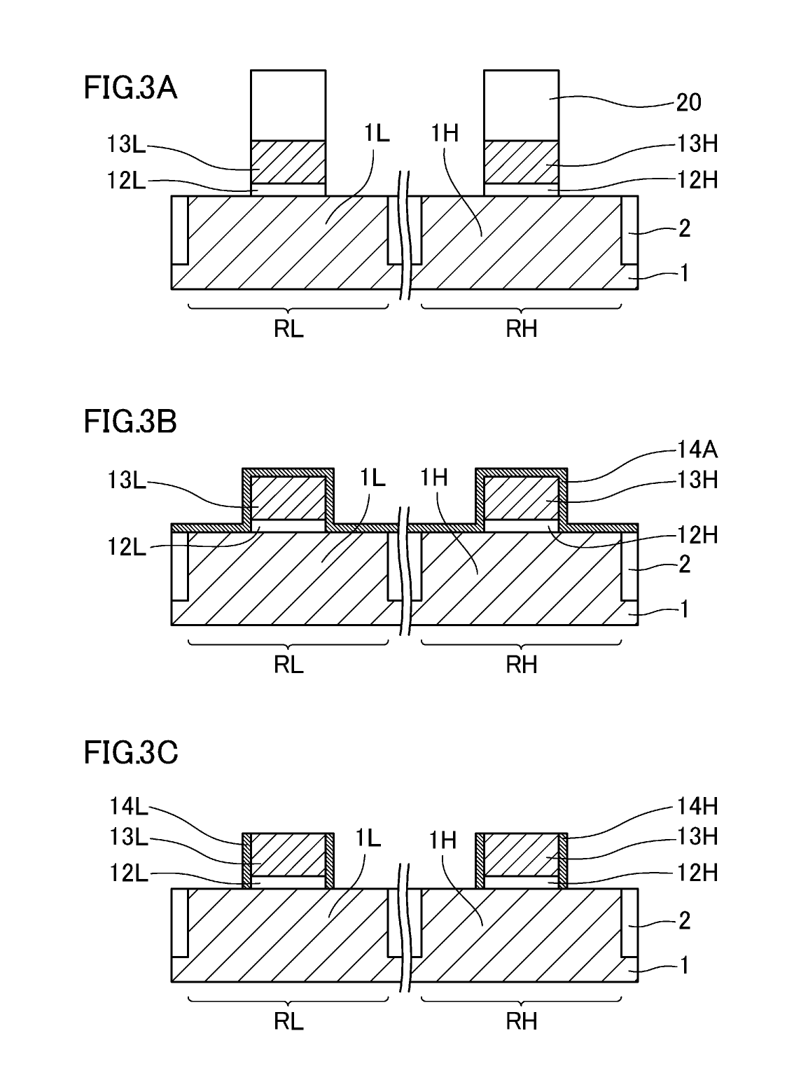

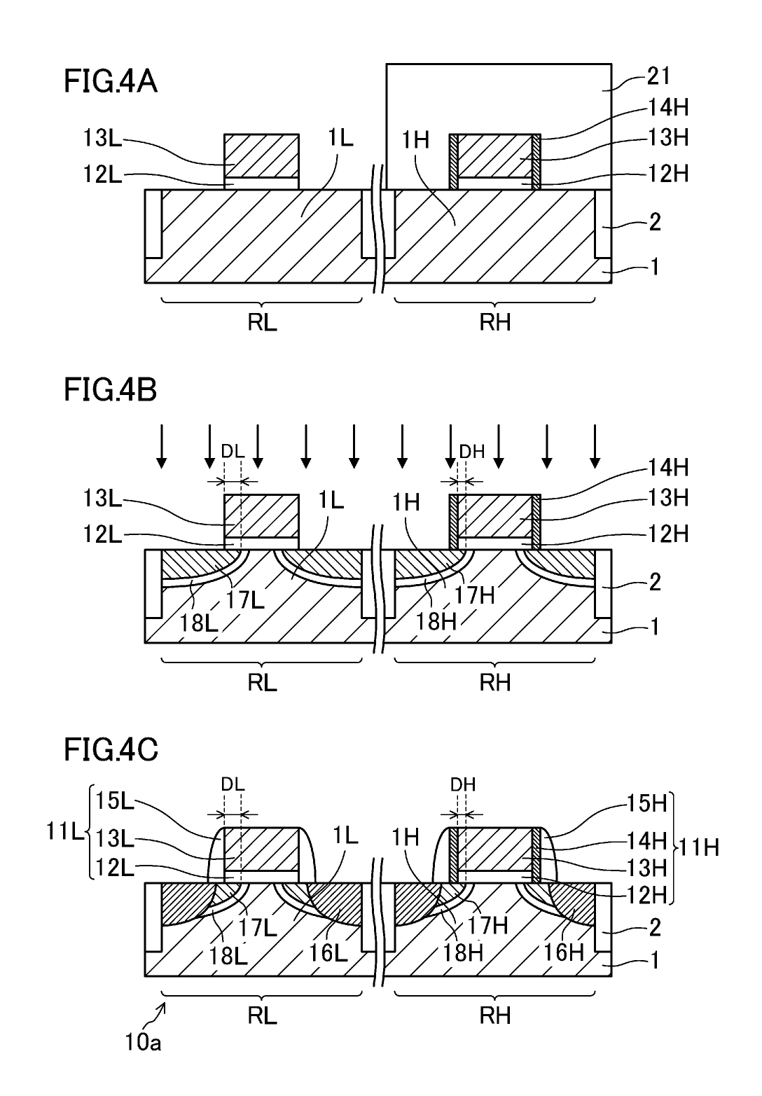

FIGS. 3(a)-3(c) and 4(a)-4(c) are views schematically illustrating a structure of an example semiconductor device 10a of the present embodiment and a method for fabricating the semiconductor device 10a. The same reference numerals as those shown in the semiconductor device 10 of the first embodiment are used to represent equivalent elements in the semiconductor device 10a illustrated in FIG. 4(c), and differences between the semiconductor device 10 and the semiconductor device 10a will be described below in detail.

As illustrated in FIG. 4(c), an Lvt transistor formation region RL where an Lvt transistor having a lower threshold voltage is formed and an Hvt transistor formation region RH where an Hvt transistor having a threshold voltage higher than that of the Lvt transistor is formed are also provided in the semiconductor device 10a.

In the Lvt transistor formation region RL, a gate electrode 13L is formed on an active region 1L of a P-type substrate 1 surrounded by element isolation regions 2 with a gate insulating film 12L being interposed between the gate electrode 13L and the active region 1L. On a side wall of the gate electrode 13L, a side wall spacer 15L is formed so as to contact the side wall of the gate electrode 13L without interposing an offset spacer between the side wall spacer 15L and the gate electrode 13L. The gate insulating film 12L, the gate electrode 13L, and the side wall spacer 15L form a gate structure 11L in the Lvt transistor formation region RL.

N-type extension regions 17L are formed below the gate electrode 13L so that each of the extension regions 17L overlaps the gate electrode 13L by an overlap amount DL. N-type source/drain regions 16L are formed on an outer side relative to the extension regions 17L, and a P-type halo region 18L is formed between each of the extension regions 17L and the substrate 1 so as to cover a lower side of the each of the extension regions 17L.

Next, in the Hvt transistor formation region RH, a gate electrode 13H is formed on an active region 1H of the P-type substrate 1 surrounded by the element isolation regions 2 with a gate insulating film 12H being interposed between the gate electrode 13H and the active region 1H. A side wall spacer 15H is formed on a side wall of the gate electrode 13H with an offset spacer 14H being interposed between the side wall spacer 15H and the gate electrode 13H. The gate insulating film 12H, the gate electrode 13H, the offset spacer 14H, and the side wall spacer 15H form a gate structure 11H in the Hvt transistor formation region RH.

N-type extension regions 17H are formed below the gate electrode 13H so that each of the extension regions 17H overlaps the gate electrode 13H by an overlap amount DH. N-type source/drain regions 16H are formed on an outer side relative to the extension regions 17H, and a P-type halo region 18H is formed between each of the extension regions 17H and the substrate 1 so as to cover a lower side of the each of the extension regions 17H.

The overlap amount DL in the Lvt transistor is longer than the overlap amount DH in the Hvt transistor. Thus, the distance (effective gate length) of part of the extension region 17L below the gate electrode 13L of the Lvt transistor is shorter than the distance of part of the extension region 17H below the gate electrode 13H of the Hvt transistor.

This allows the threshold voltage of the Lvt transistor to be lower than the threshold voltage of the Hvt transistor.

The offset spacer is not provided in the Lvt transistor, and the offset spacer 14H is provided in the Hvt transistor. This provides a difference between the overlap amounts DL and DH.

Next, the method for fabricating the semiconductor device 10a will be described with reference to FIGS. 3(a)-3(c) and 4(a)-4(c).

FIG. 3(a) illustrates a state in which gate electrodes are formed. The gate electrodes may be similarly formed as described in the first embodiment with reference to FIG. 1(a). After a configuration illustrated in FIG. 3(a) is obtained, a resist 20 is removed.

Next, as illustrated in FIG. 3(b), an insulating film 14A to be formed into offset spacers is formed so as to cover upper and side surfaces of gate electrodes 13L and 13H. For example, a SiN film or a SiO₂ film is used to form the insulating film 14A to a film thickness of 2-10 nm by the CVD.

Next, as illustrated in FIG. 3(c), anisotropic etching is performed on an entire surface of a substrate 1 to etch back the entirety of the insulating film 14A. Other than part of the insulating film 14A covering side walls of the gate electrodes, the insulating film 14A is removed. In such a manner, the offset spacers are formed. More specifically, an offset spacer 14H is formed so as to cover the side wall of the gate electrode 13H in the Hvt transistor formation region RH. An offset spacer 14L is formed so as to cover the side wall of the gate electrode 13L in the Lvt transistor formation region RL.

Next, as illustrated in FIG. 4(a), the offset spacer 14L in the Lvt transistor formation region RL is removed. For this purpose, a resist is applied and patterned into a resist 21 covering only the Hvt transistor formation region RH. Wet etching is performed by using the resist 21 as a mask, and the offset spacer 14L in the Lvt transistor formation region RL is selectively removed. Subsequently, the resist 21 is removed.

Next, as illustrated in FIG. 4(b), N-type extension regions and P-type halo regions are formed.

First, ion implantation of As or P which is an N-type impurity is performed as extension implantation under the similar conditions to those described in the first embodiment.

In such a state, in Lvt transistor formation region RL, only gate electrode 13L is used as a mask, thereby forming extension regions 17L in an active region 1L. Each of the extension regions 17L is formed below the gate electrode 13L so as to overlap the gate electrode 13L by an overlap amount DL.

In addition, in the Hvt transistor formation region RH, the gate electrode 13H and the offset spacer 14H are used as a mask. Each of extension regions 17H is formed below the gate electrode 13H so as to overlap the gate electrode 13H by an overlap amount DH.

The offset spacer 14H is formed only in the Hvt transistor formation region RH. Thus, even if the extension implantation is similarly performed to the Lvt transistor formation region RL and the Hvt transistor formation region RH, the overlap amount DL is longer than the overlap amount DH. Consequently, an effective gate length difference between an Lvt transistor and an Hvt transistor can be provided without separately performing a masking step and an implanting step, thereby providing a plurality of field-effect transistors having different threshold voltages on the same substrate.

Subsequently, a halo region 18L covering a lower side of the extension region 17L and positioned between the extension region 17L and the substrate 1 is formed, and a halo region 18H covering a lower side of the extension region 17H and positioned between the extension region 17H and the substrate 1 is formed. For this purpose, ion implantation of B, BF₂, or In which is a P-type impurity is performed. Implantation conditions may be similar to those of the first embodiment.

The thickness of the offset spacer 14H in the Hvt transistor formation region RH is set depending on a required gate length difference.

For example, suppose that a desired threshold voltage difference between the Lvt transistor and the Hvt transistor is about 50-100 mV. In addition, suppose that, when an effective gate length varies by 8 nm, a threshold voltage varies by 100 mV. In such a case, the effective gate length difference between the Lvt transistor and the Hvt transistor may be 4-8 nm. Thus, the offset spacer 14H may be formed so as to have a thickness of 2-4 nm.

Consequently, the overlap amount DH is increased (as compared to the overlap amount DL) by 2-4 nm on each side of the gate electrode 13H, thereby obtaining an effective gate length difference of 4-8 nm. Note that the foregoing values have been set forth for purpose of preferred example, and an offset spacer thickness difference can be set based on, e.g., the dimension of the gate electrode, the concentrations of various impurity regions, and the desired threshold voltage difference.

Next, as illustrated in FIG. 4(c), side wall spacers and source/drain regions are formed.

First, an insulating film is formed on the substrate 1 so as to cover the gate electrodes 13L and 13H etc., and anisotropic dry etching is performed for the insulating film. In such a manner, the followings are formed: a side wall spacer 15L contacting a side surface of the gate electrode 13L; and a side wall spacer 15H formed on the side wall of the gate electrode 13H with the offset spacer 14H being interposed between the side wall spacer 15H and the gate electrode 13H.

After the foregoing steps, a gate structure 11L is formed in the Lvt transistor formation region RL, and a gate structure 11H is formed in the Hvt transistor formation region RH.

Subsequently, ion implantation of an N-type impurity such as As is performed to the active regions 1L and 1H by using the gate structures 11L and 11H as a mask, thereby forming an N-type source/drain region 16L on each side of the gate structure 11L and forming an N-type source/drain region 16H on each side of the gate structure 11H.

In the foregoing manner, a semiconductor device 10a is formed. According to the foregoing fabricating method, the field-effect transistors having different threshold voltages can be formed without increasing the number of masking steps, thereby shortening a fabricating process.

Note that the first and second embodiments may be combined to provide three types of field-effect transistors having different threshold voltages. That is, the presence/absence of the offset spacer and the difference in thickness of the offset spacer are set, and therefore three or more possible overlap amounts of the gate electrode and the extension region can be set by performing the extension implantation once.

Although the N-channel transistor has been described as the example in both of the first and second embodiments, each of the configurations of the first and second embodiments may be applied to a P-channel transistor.

The channel implantation may be performed separately to the Lvt transistor and the Hvt transistor. Although the number of steps for the channel implantation is increased, controllability of the threshold voltage can be further improved.

According to the technique of the present disclosure, the semiconductor device including the plurality of field-effect transistors having different threshold voltages and the method for fabricating the semiconductor device can be realized while reducing the increase in number of fabricating steps. The technique of the present disclosure can be applied to reduce the size of the semiconductor device.

What is claimed is:

1. A semiconductor device, comprising:
first and second field-effect transistors provided on a substrate and having the same conductivity type,
wherein the first field-effect transistor include
a first gate electrode formed on a first active region of the substrate,
a first side wall spacer formed on a side wall of the first gate electrode, and
first extension regions respectively formed in the first active region on sides sandwiching part of the first active region below the first gate electrode and having a first conductivity type,
the second field-effect transistor include
a second gate electrode formed on a second active region of the substrate,
a second side wall spacer formed on a side wall of the second gate electrode, and
second extension regions respectively formed in the second active region on sides sandwiching part of the second active region below the second gate electrode and having the first conductivity type,
the second field-effect transistor has a threshold voltage higher than that of the first field-effect transistor,
a length in a gate length direction, by which each of the first extension regions and the first gate electrode overlap each other, is longer than a length in the gate length direction, by which each of the second extension regions and the second gate electrode overlap each other, and
a distance between the first gate electrode and the first side wall spacer is shorter than a distance between the second gate electrode and the second side wall spacer.

2. The semiconductor device of claim 1, wherein
a first offset spacer is provided between the first side wall spacer and the first gate electrode, and
a second offset spacer thicker than the first offset spacer is provided between the second side wall spacer and the second gate electrode.

3. The semiconductor device of claim 2, wherein
at least the second offset spacer of the first and second offset spacers has a multi-layer structure with two or more layers, and
the number of layers of the second offset spacer is greater than that of the first offset spacer.

4. The semiconductor device of claim 1, wherein
the first side wall spacer contacts the side wall of the first gate electrode, and
an offset spacer is provided between the second side wall spacer and the second gate electrode.

5. The semiconductor device of claim 1, wherein
the length in the gate length direction, by which each of the first extension regions and the first gate electrode overlap each other, is longer than the length in the gate length direction, by which each of the second extension regions and the second gate electrode overlap each other, by a predetermined distance.

6. The semiconductor device of claim 5, wherein
the predetermined distance is set depending on a difference between the threshold voltage of the first field-effect transistor and the threshold voltage of the second field-effect transistor.

7. The semiconductor device of claim 5, wherein
the predetermined distance is equal to or greater than 2 nm and equal to or less than 4 nm.

8. The semiconductor device of claim 1, wherein
the distance between the first gate electrode and the first side wall spacer is shorter than the distance between the second gate electrode and the second side wall spacer by a predetermined distance.

9. The semiconductor device of claim 8, wherein
the predetermined distance is set depending on a difference between the threshold voltage of the first field-effect transistor and the threshold voltage of the second field-effect transistor.

10. The semiconductor device of claim 8, wherein
the predetermined distance is equal to or greater than 2 nm and equal to or less than 4 nm.

11. The semiconductor device of claim 1, wherein
a dimension of the first gate electrode in the gate length direction and a dimension of the second gate electrode in the gate length direction are substantially the same.

12. The semiconductor device of claim 1, wherein
a distance of part of the first extension region below the first gate electrode is shorter than a distance of part of the second extension region below the second gate electrode.

13. The semiconductor device of claim 1, further comprising:
a first halo region provided between each of the first extension regions and the substrate and having a second conductivity type; and
a second halo region provided between each of the second extension regions and the substrate and having the second conductivity type.

14. The semiconductor device of claim 1, further comprising:
first source/drain regions each formed in the first active region on an outer side relative to each of the first extension regions as viewed from the first gate electrode and having the first conductivity type; and
second source/drain regions each formed in the second active region on an outer side relative to each of the second extension regions as viewed from the second gate electrode.

15. A method for fabricating a semiconductor device including a first field-effect transistor having a first gate electrode and a second field-effect transistor having a second gate electrode, the method comprising:
forming the first gate electrode on a first active region of a substrate and forming the second gate electrode on a second active region of the substrate;
forming a first offset spacer on a side wall of the first gate electrode and forming a second offset spacer thicker than the first offset spacer on a side wall of the second gate electrode; and
after the forming the first and second offset spacers, performing first impurity implantation to the first active region by using the first gate electrode and the first offset spacer as a mask to respectively form first extension regions having a first conductivity type in the first active region on both sides relative to the first gate electrode, and performing the first impurity implantation to the second active region by using the second gate electrode and the second offset spacer as a mask to respectively form second extension regions having the first conductivity type in the second active region on both sides relative to the second gate electrode.

16. The method of claim 15, wherein
at least the second offset spacer of the first and second offset spacers has a multi-layer structure with two or more layers, and
the number of layers of the second offset spacer is greater than that of the first offset spacer.

17. The method of claim 15, wherein
after the performing first impurity implantation, first and second side wall spacers are formed on the side walls of the first and second electrodes, respectively, and
second impurity implantation is then performed to the first and second active regions to form first source/drain regions having the first conductivity type in the first active region on an outer side relative to the first side wall spacer as viewed from the first gate electrode and form second source/drain regions having the first conductivity type in the second active region on an outer side relative to the second side wall spacer as viewed from the second gate electrode.

18. A method for fabricating a semiconductor device including a first field-effect transistor having a first gate electrode and a second field-effect transistor having a second gate electrode, the method comprising:
forming the first gate electrode on a first active region of a substrate and forming the second gate electrode on a second active region of the substrate;
forming an offset spacer on a side wall of the second gate electrode; and
after the forming an offset spacer, performing first impurity implantation to the first active region by using the first gate electrode as a mask to respectively form first extension regions having a first conductivity type in the first active region on both sides relative to the first gate electrode, and performing the first impurity implantation to the second active region by using the second gate electrode and the offset spacer as a mask to respectively form second extension regions having the first conductivity type in the second active region on both sides relative to the second gate electrode,
wherein, in the performing first impurity implantation, the first impurity implantation is performed in a state in which an offset spacer is not formed on a side wall of the first gate electrode.

19. The method of claim 18, wherein
after the performing first impurity implantation, first and second side wall spacers are formed on the side walls of the first and second gate electrodes, respectively, and
second impurity implantation is then performed to the first and second active regions to form first source/drain regions having the first conductivity type in the first active region on an outer side relative to the first side wall spacer as viewed from the first gate electrode and form second source/drain regions having the first conductivity type in the second active region on an outer side relative to the second side wall spacer as viewed from the second gate electrode.
